(19) United States
(12) Patent Application Publication
(10) Pub. No.: US 2006/0270234 A1
(43) Pub. Date: Nov. 30, 2006

(54) Method and composition for preparing a semiconductor surface for deposition of a barrier material

(76) Inventors: Varughese Mathew, Austin, TX (US); Edward Acosta, Martindale, TX (US); Sam S. Garcia, Austin, TX (US); Lynne M. Michaelson, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/140,162

(22) Filed: May 27, 2005

(51) Int. Cl. H01L 21/302; H01L 21/461

(52) U.S. Cl. 438/692; 438/689

(57) ABSTRACT

A method for making a semiconductor device includes cleaning a semiconductor wafer after a chemical mechanical polishing (CMP) process to remove or reduce particles of copper, a corrosion inhibitor such as triazole, and a copper oxide layer on the copper layer. In order to prepare for plating the copper layer with a layer that functions as a barrier to copper migration or diffusion, the surface of the copper layer and the dielectric layer are treated with an oxidant, a surfactant, and copper-chelating agent. The copper-chelating is preferably a mild acid such as an organic acid. The oxidant is particularly useful in removing the corrosion inhibitor. The barrier layer, preferably conductive, is then plated on the surface of the copper layer. Subsequent interlayer dielectric layers and copper layers follow that can use the same process.

### RELATED APPLICATIONS

A related, copending application is entitled “Method of Using an Aqueous Solution and Composition Therefor”, by Cooper et al., application Ser. No. 10/430,987, assigned jointly to Freescale Semiconductor and Advanced Micro Devices, and was filed on May 7, 2003.

A related, copending application is entitled “Method To Passivate Conductive Surfaces During Semiconductor Processing”, by Flake et al., application Ser. No. 10/431,053 assigned jointly to Freescale Semiconductor and Advanced Micro Devices, and was filed on May 7, 2003.

A related, copending application is entitled “Method Of Forming A Semiconductor Device Having A Diffusion Barrier Stack And Structure Thereof”, by Michaelson et al., application Ser. No. 11/078,236, assigned to the assignee hereof, and was filed on Mar. 11, 2005.

A related, copending application is entitled “Semiconductor Process and Composition for Forming a Barrier Material Overlying Copper”, by Mathew et al., application Ser. No. 10/650,002, assigned to the assignee hereof, and was filed on Aug. 27, 2003. ==

### FIELD OF THE INVENTION

The present invention relates generally to semiconductors, and more particularly, to a method and composition for preparing a copper surface for deposition of a diffusion barrier by electroless plating.

### BACKGROUND OF THE INVENTION

In integrated circuits, a dielectric layer is used to provide insulation around the interconnect wiring of the chip. Just as faster interconnect materials such as copper allow a signal to move faster through the chip, decreasing the capacitance factor of the insulating material also allows signals to travel across the interconnect faster because they have less interference with each other. The most common dielectric material is silicon dioxide. However, the semiconductor industry is constantly searching for commercially useful, lower capacitance dielectric materials, commonly referred to as low dielectric constant or low k materials.

Conventional cobalt (Co) films doped with elements like tungsten (W), molybdenum (Mo), rhenium (Re), etc. are reported to have barrier properties to prevent diffusion of copper into a surrounding dielectric material. This can enable integration of copper with low k materials. Also capping copper with these types of materials can enhance reliability by increasing electro-migration resistance. In order to be successful a very selective deposition of these films is required. Also, formation of the barrier is highly dependent on the condition of the copper surface.

Chemical mechanical polishing (CMP) has been widely adopted in semiconductor manufacturing processes for planarization of a layer, especially a copper layer on a wafer surface. More specifically, a copper layer is deposited over a dielectric layer to fill openings within the dielectric layer. To remove portions of the copper layer that are not within the openings (i.e., to form interconnects that are electrically isolated from each other), a slurry and a pad are used. The wafer may be rinsed following planarization to remove any unwanted surface defects, or other residuals.

There may be additives in the CMP solution for inhibiting corrosion such as an azole-based corrosion inhibitor. The azole-based corrosion inhibitor, such as benzotriazole, remains on the wafer after CMP and is included to prevent the copper from oxidizing. However, azole-based corrosion inhibitor may block nucleation sites for electroless deposition on the copper surface. Also, the azole-based corrosion inhibitor can be leached into a cobalt plating bath and can affect the plating process including stopping the plating process altogether. In addition, during the CMP process, copper particles can be smeared and trapped on the dielectric surfaces which could act as catalytic or nucleation centers for, for example, CoWB growth. This will lead to increased leakage after CoWB deposition. In addition, copper oxide on the surface may need to be removed or reduced before plating.

Therefore, there is a need for a copper preparation process and solution that can reduce azoles and remove copper oxides without increased leakage and without significantly removing the copper itself.

### BRIEF DESCRIPTION OF THE DRAWINGS

FIG. 1 illustrates a cross-sectional view of a portion of a semiconductor wafer after formation of a metal layer.

FIG. 2 illustrates a cross-sectional view of the portion of the semiconductor wafer of FIG. 1 after a portion of a metal layer has been removed.

FIG. 3 illustrates a cross-sectional view of the portion of the semiconductor wafer of FIG. 2 after formation of a diffusion barrier.

FIG. 4 illustrates a cross-sectional view of the portion of the semiconductor wafer of FIG. 3 after formation of a dielectric layer.

FIG. 5 illustrates a flow chart of method for forming the semiconductor device of FIG. 4 in accordance with one embodiment of the present invention.

FIG. 6 illustrates a flow chart of the step for applying the surface preparation solution of FIG. 5 in accordance with another embodiment of the present invention.

### DETAILED DESCRIPTION

Generally, the present invention provides, in one form, a method for preparing a semiconductor wafer for deposition of a diffusion barrier after the wafer has been planarized using a CMP process. In one embodiment, the method includes applying a surface preparation solution comprising an organic acid, a surfactant, and an oxidant to a semiconductor wafer after the CMP process. The surface preparation solution may be applied to the wafer as one solution, or may be applied to the wafer as two solutions that are applied separately in a two step process. In a first step of the two step process, a solution comprising an organic acid and a surfactant is applied to the wafer. In a second step, a solution comprising an organic acid and an oxidant is applied to the wafer.

The surface preparation solution, when applied to a semiconductor wafer after CMP, will remove, or reduce, azole-based corrosion inhibitors such as triazole, surface oxide, and copper particles without removing an excessive amount of copper. Also, the copper that is removed is removed nearly uniformly independent of metal feature size and metal feature density.

FIG. 1 illustrates a cross-sectional view of a portion of a semiconductor wafer 10. The semiconductor wafer is processed to produce semiconductor devices having integrated circuits implemented thereon. Semiconductor wafer 10 includes a substrate 12 having an active region. An insulating layer 22 is formed on a surface of the substrate 12. In the illustrated embodiment, the insulating layer 22 is a gate dielectric layer for implementing a plurality of transistors. A polysilicon layer 14 is formed on the insulating layer 22 and patterned to be, for example, a gate electrode of a complementary metal-oxide semiconductor (CMOS) transistor. An insulating layer 20 is formed over the polysilicon layer 14 and removed in areas where electrical contact to polysilicon layer 14 is needed. One or more interconnect layers comprising metal will be formed over the active circuitry to serve as wiring layers for the integrated circuits. A contact 16 is formed through insulating layer 20 and makes electrical contact with the polysilicon layer 14. The contact 16 will connect the polysilicon layer to one or more metal layers that will be formed above the polysilicon layer 14. The contact 16 may be formed from tungsten (W) or some other suitable conductive material. A barrier layer 24 is then formed over the insulating layer 20 and lines the sides and bottom of a trench 18 in the insulating layer 20. The barrier layer functions as a barrier to electro-migration or diffusion. A metal layer 19 is formed over the barrier layer 24 and fills the trench 18. In the illustrated embodiment, the metal layer 19 is formed from copper. However, in other embodiments, the metal layer 19 may be formed from another metal such as aluminum. Also in other embodiments, the metal layer 19 may be one of many metal interconnect layers.

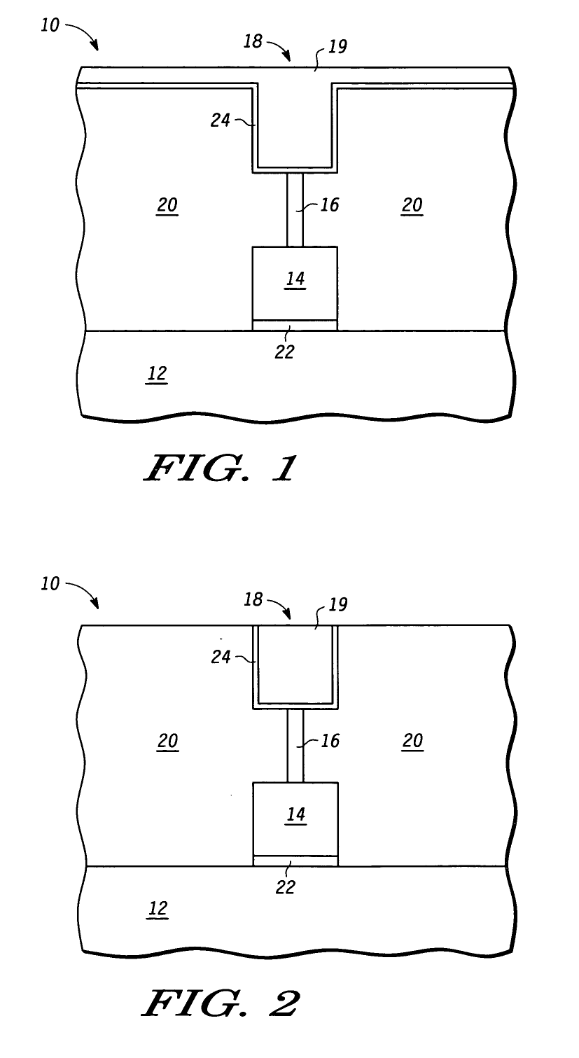

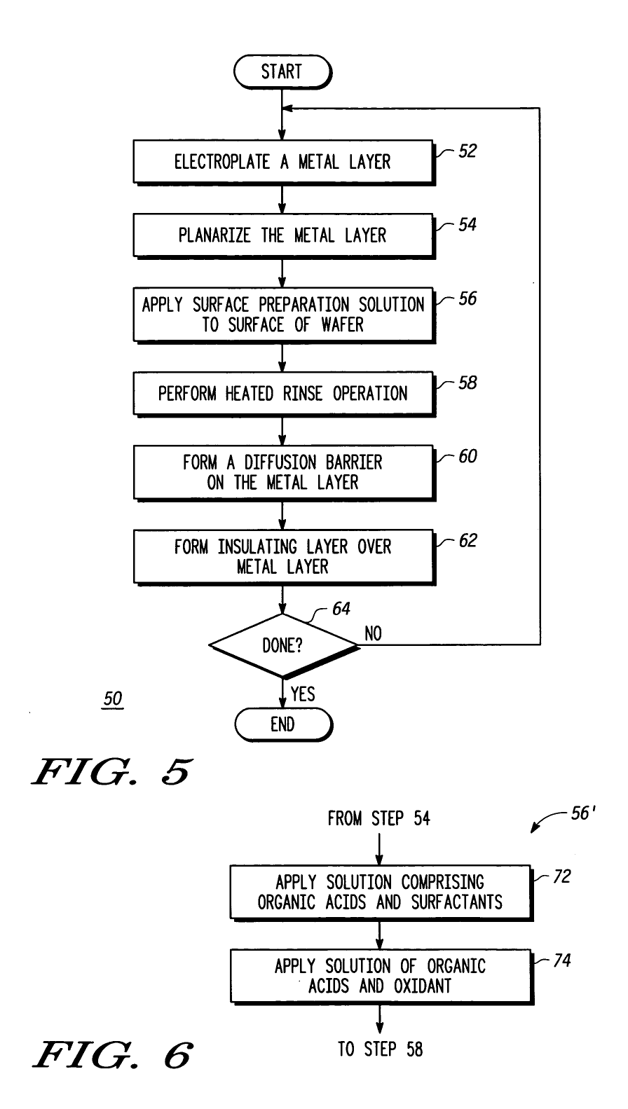

FIG. 2 illustrates a cross-sectional view of the semiconductor device 10 of FIG. 1 after a portion of the metal layer 19 has been removed using a conventional chemical mechanical polishing (CMP) process. As illustrated in FIG. 2, all of metal layer 19 is removed except for the metal filling the trench 18. There may be additives in the CMP solution for inhibiting corrosion such as an azole-based corrosion inhibitor. After the CMP process is complete, the surface of the semiconductor wafer is cleaned using a method illustrated in FIG. 5, which will be discussed later.

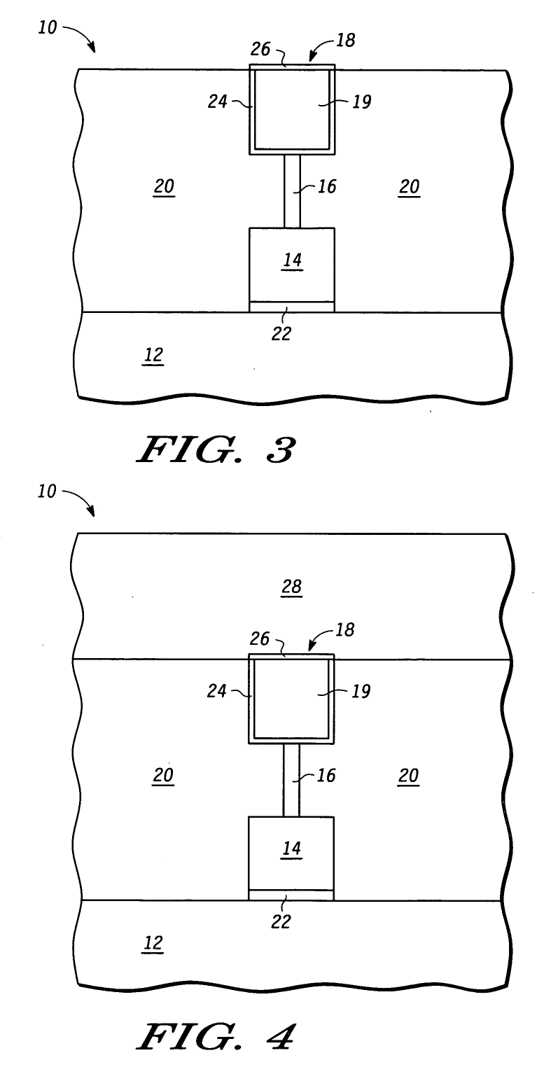

FIG. 3 illustrates a cross-sectional view of the portion of the semiconductor wafer 10 of FIG. 2 after formation of a diffusion barrier 26. In the illustrated embodiment the diffusion barrier 26 includes a cobalt (Co) film doped with tungsten (W) and boron (B). Also, the diffusion barrier 26 may include nickel (Ni). Also, the diffusion barrier 26 may be doped with elements like molybdenum (Mo), rhenium (Re), and phosphorus (P). Thus, for example, the diffusion barrier 26 may comprise one or more of CoWP, CoWB, CoWPB, CoReP, CoReB, CoRePB, CoMoP, CoMoB, CoMoPB, NiWP, NiWB, NiWPB, NiReP, NiReB, NiRePB, NiMoP, NiMoB, NiMoPB, and the like The diffusion barrier functions to prevent copper from diffusing into the upper insulating layer 28 (FIG. 4). Also, the diffusion barrier may function to reduce electro-migration.

FIG. 4 illustrates a cross-sectional view of the portion of the semiconductor wafer 10 of FIG. 3 after an insulating layer 28 is formed. Following the formation of the insulating layer 28, one or more additional metal interconnect layers may be formed over the insulating layer 28. The insulating layer 28 may be patterned to form one or more copper vias for subsequent metal layers if additional metal layers are needed. The metal layers, including metal layer 19 for providing conductors for electrically connecting the circuits in the active layers on the semiconductor device.

FIG. 5 illustrates a flow chart 50 of a method for forming the semiconductor device 10 of FIG. 4 in accordance with one embodiment of the present invention. At step 52, a metal, such as for example copper is formed in a surface of the semiconductor wafer. Preferably, the metal layer is electroplated. After electroplating the copper on a semiconductor device such as a wafer including an integrated circuit, the copper is annealed, and then the surface of the metal is smoothed and polished during a planarizing step 54. For example, the metal may be planarized using a chemical mechanical polishing (CMP) technique.

After planarization, the surface may need to be “pre-cleaned” to remove impurities introduced during the CMP process. At step 56 of FIG. 5, a “one-step” surface preparation solution for pre-cleaning the surface of the wafer is applied to the semiconductor wafer. The solution may also be applied in two steps as illustrated in FIG. 6 and discussed later. Generally, the solution comprises organic acids that function as copper-chelating agents, surfactants, and an oxidant. In one embodiment, the organic acids may be carboxylic and the oxidant is a persulfate such as for example ammonium persulfate. In another embodiment, the oxidant may be hydrogen peroxide.

More specifically, the surface preparation solution includes 20-60 grams/liter malic acid, 20-60 grams/liter citric acid, 20-60 parts-per-million (ppm) of an anionic surfactant such as Zonyl® FSJ or Zonyl® FSP, 20-60 ppm of a nonionic surfactant such as Zonyl® FS300, and 20-60 grams/liter of ammonium persulfate. Zonyl® FSJ, Zonyl® FSP, and Zonyl® FS300 are available from the Dupont Corporation and Zonyl® is a registered trademark of Dupont Corporation. In the one-step method, surfactant Zonyl® FSP is preferred over Zonyl® FSJ because it has been shown to be more stable when mixed with the oxidant ammonium persulfate. The solution is applied by spraying the wafer for about 30 seconds to 300 seconds or more preferably around 120 seconds at temperatures ranging from 20 to 45 degrees Celsius or more preferably around 25 degrees Celsius. The solution may be sprayed on the wafer or the wafer may be immersed in the solution. Note that in other embodiments, the malic or citric acids may be substituted by other water soluble acids such as carboxylic acids, such as tartaric, oxalic acid, etc. Also, in other embodiments, only one surfactant may be used.

At step 58, after applying the solution at step 56, a heated rinse operation may be optionally performed. The wafer is sprayed with de-ionized water that has been heated to about 30 to 70 degrees Celsius for about 30 to 120 seconds. At step 60, a diffusion barrier is formed on the metal layer after step 58. The diffusion barrier, such as the diffusion barrier 26 of FIG. 4, is formed on the metal layer using a conventional electroless plating technique. In another embodiment, a conductive material may be formed on the metal layer instead of the diffusion barrier. The conductive material is formed to improve electro-migration resistance. Alternately, the conductive material may be formed with a diffusion barrier. Then, at step 62, an insulating layer, such as insulating layer 28 in FIG. 4 is formed over the metal layer. At decision step 64, it is determined if more metal layers are to be formed. If more layers are needed, the flow returns to step 52 and the method is repeated until all of the metal layers, including interconnects between the layers, are formed. When all of the metal layers have been formed on the semiconductor wafer, the flow ends.

FIG. 6 illustrates a flow chart of a step 56′ for applying the surface preparation solution of FIG. 5 in accordance with another embodiment of the present invention. In FIG. 6, the surface preparation solution is applied in two steps after step 54 in FIG. 5 and instead of step 56. In the first step, step 72, a solution comprising organic acids and surfactants are sprayed on the wafer at temperatures ranging from 20 to 45 degrees Celsius or more preferably 25 degrees Celsius for 30 to 180 seconds or more preferably 90 seconds. The organic acids include malic acid and citric acid in the same quantities as described above for FIG. 5. Preferably, the surfactant comprises either Zonyl® FSJ or Zonyl® FSP. Note that in the embodiment of FIG. 5, Zonyl® FSP is preferred because it is more stable when combined with the ammonium persulfate. In the second step, step 74, a solution comprising organic acids and an oxidant is sprayed on the wafer at temperatures ranging from 20 to 45 degrees Celsius or more preferably 25 degrees Celsius for 30 to 120 seconds or more preferably 60 seconds. The organic acids include malic acid and citric acid in the same quantities as described above for FIG. 5. The oxidant is preferably ammonium persulfate in the quantities described in FIG. 5. After step 74, the flow continues with step 58 in FIG. 5.

The surface preparation solution as described above has been determined to remove the azole-based corrosion inhibitors that are applied as part of a CMP process. Also, surface oxide and copper particles are removed while only removing a small amount of copper. Further, the amount of copper removed is removed nearly uniformly, independent of metal feature size and metal feature density.

While the invention has been described in the context of a preferred embodiment, it will be apparent to those skilled in the art that the present invention may be modified in numerous ways and may assume many embodiments other than that specifically set out and described above. Accordingly, it is intended by the appended claims to cover all modifications of the invention which fall within the true scope of the invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A method for making a semiconductor device, comprising:
providing a semiconductor substrate;
providing a first dielectric layer over the substrate;
depositing a metal layer comprising copper on the dielectric layer;
chemical mechanical polishing (CMP) the metal layer using a CMP solution comprising a corrosion inhibitor;
preparing the metal layer by applying a cleaning solution to the metal layer after the CMP, the cleaning solution comprising a surfactant, an oxidant, and a first acid, the cleaning solution for removing the corrosion inhibitor and a portion of the copper; and
forming a conductive layer on the metal layer.

2. The method of claim 1, further comprising forming a second dielectric layer on the conductive layer and the first dielectric layer.

3. The method of claim 1, wherein preparing the metal layer further comprises:
applying a first solution comprising the first acid and the surfactant; and
applying a second solution comprising the oxidant and a second acid.

4. The method of claim 3, further comprising applying heated de-ionized water to the metal layer after applying the second solution.

5. The method of claim 4, wherein the first acid and the second acid are organic.

6. The method of claim 5, wherein the first acid and the second acid are carboxylic.

7. The method of claim 3, wherein the first acid comprises one of a group consisting of citric acid, malic acid, tartaric acid, and oxalic acid.

8. The method of claim 3, wherein the second acid comprises at least one of citric acid, malic acid, tartaric acid, and oxalic acid.

9. The method of claim 1, wherein the metal layer comprises an underlying conductive liner and an overlying copper layer.

10. The method of claim 1, wherein the metal layer remaining after the CMP is present in a trench in the first dielectric layer.

11. The method of claim 1, wherein the corrosion inhibitor is an azole-based corrosion inhibitor.

12. The method of claim 1 wherein the surfactant is characterized as being anionic.

13. The method of claim 1, wherein the oxidant comprises a persulfate.

14. The method of claim 13, wherein the persulfate comprises ammonium persulfate.

15. The method of claim 1, wherein the oxidant comprises hydrogen peroxide.

16. The method of claim 1, wherein the forming the conductive layer comprises plating the metal layer with one of cobalt or nickel for use as a barrier.

17. The method of claim 1, wherein the forming the conductive layer comprises plating the metal layer with an alloy comprising cobalt and tungsten.

18. A method of plating, comprising:
providing a semiconductor substrate;
providing a first dielectric layer over the substrate;
depositing a copper-containing layer on the dielectric layer;
chemical mechanical polishing (CMP) the copper-containing layer using a CMP solution comprising a corrosion inhibitor;
applying a copper-chelating agent, an oxidant, and a surfactant to a surface of a the copper-containing layer after the CMP to remove the corrosion inhibitor and a portion of the copper; and
plating the surface of the copper-containing layer with a metal that comprises one of a group consisting of nickel and cobalt.

19. The method of claim 18, wherein the oxidant comprises one of a group consisting of hydrogen peroxide and a persulfate.

20. A method of making a semiconductor device, comprising:
providing a semiconductor substrate;
providing a first conductive layer over the substrate;
providing a first dielectric layer over the first conductive layer;
forming a trench in the dielectric layer and a contact between the trench and the first conductive layer;
forming a copper-containing layer over the dielectric layer and in the trench;
chemical mechanical polishing (CMP) the copper-containing layer to leave the copper-containing layer in the trench, expose a surface of the dielectric layer, and form a corrosion inhibitor on the copper-containing layer;
cleaning the metal layer and the dielectric layer after the CMP by applying a surfactant, an oxidant, and a copper-chelating agent to the copper-containing layer and the dielectric layer to remove the corrosion inhibitor and a portion of the copper-containing layer; and
plating a second conductive layer on the copper-containing layer.
